(19) United States
(12) Patent Application Publication
(10) Pub. No.: US 2015/0303392 A1
(43) Pub. Date: Oct. 22, 2015

(54) LIGHT-EMITTING ELEMENT, LIGHT-EMITTING DEVICE, ELECTRONIC DEVICE, AND LIGHTING DEVICE

(71) Applicant: Semiconductor Energy Laboratory Co., Ltd., Atsugi-shi (JP)

(72) Inventors: Nobuharu OHSAWA, Kanagawa (JP); Yusuke NONAKA, Kanagawa (JP)

(21) Appl. No.: 14/685,758

(22) Filed: Apr. 14, 2015

(30) Foreign Application Priority Data
Apr. 18, 2014 (JP) 2014-086196

(51) Int. Cl. H01L 51/50

(52) U.S. Cl. CPC H01L 51/504; H01L 51/5016; H01L 2251/5376

(57) ABSTRACT

The light-emitting element includes an EL layer between a pair of electrodes. The EL layer includes a light-emitting layer. The light-emitting layer includes a first light-emitting layer and a second light-emitting layer. The first light-emitting layer and the second light-emitting layer contain light-emitting substances emitting light with different colors. Any one of the first light-emitting layer and the second light-emitting layer is not formed partly so that the light-emitting layer includes a region where the any the other of the first light-emitting layer and the second light-emitting layer is only formed. A first light emitted from a region of the light-emitting layer where the first light-emitting layer and the second light-emitting layer overlap with each other is different in color from a second light emitted from a region including the non-formation region. The first light and the second light can be obtained from the light-emitting layer at the same time.

### BACKGROUND OF THE INVENTION

1. Field of the Invention

One embodiment of the present invention relates to a light-emitting element in which an organic compound capable of providing light emission by application of an electric field is provided between a pair of electrodes, and also relates to a light-emitting device, an electronic device, and a lighting device including such a light-emitting element.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting device, a lighting device, a power storage device, a storage device, a method for driving any of them, and a method for manufacturing any of them.

2. Description of the Related Art

A light-emitting element using an organic compound as a luminous body, which has features such as thinness, lightness, high-speed response, and DC drive at low voltage, is expected to be used in a next-generation flat panel display. In particular, a display device in which light-emitting elements are arranged in matrix is considered to have advantages in a wide viewing angle and excellent visibility over a conventional liquid crystal display device.

The light emission mechanism is said to be as follows: when a voltage is applied between a pair of electrodes with an EL layer including a luminous body provided therebetween, carriers (electrons and holes) injected from the electrodes recombine to form excitons, and energy is released and light is emitted when the excitons return to the ground state. Singlet excitation (S*) and triplet excitation (T*) are known as excited states. Light emission from the singlet excited state is called fluorescence and light emission from the triplet excited state is called phosphorescence. The statistical generation ratio of the excited states in a light-emitting element is considered to be S*:T*=1:3.

In order to obtain a variety of emission colors from such light-emitting elements, improvement of a device structure, development of materials, and the like have been carried out. However, a desired white light is difficult to obtain in a white light-emitting element by combining plural emission colors, and a variety of attempts to solve this problem have been made (for example, see Patent Document 1).

### REFERENCE

### Patent Document

[Patent Document 1] Japanese Published Patent Application No. 2007-53090

### SUMMARY OF THE INVENTION

One embodiment of the present invention provides a light-emitting element that includes a light-emitting layer capable of emitting light with different colors, includes light-emitting regions corresponding to the emission colors in the light-emitting layer, and thus is capable of emitting a desired white light. One embodiment of the present invention also provides a low-power-consumption light-emitting device including the light-emitting element. Furthermore, one embodiment of the present invention provides low-power consumption electronic device and lighting device each including the light-emitting element. In addition, one embodiment of the present invention provides a novel light-emitting element, a novel light-emitting device, a novel lighting device, or the like. Note that the description of these objects does not disturb the existence of other objects. In one embodiment of the present invention, there is no need to achieve all the objects. Other objects will be apparent from and can be derived from the description of the specification, the drawings, the claims, and the like.

One embodiment of the present invention is a light-emitting element including an EL layer between a pair of electrodes. The EL layer includes a light-emitting layer. The light-emitting layer includes a first light-emitting layer and a second light-emitting layer. The first light-emitting layer and the second light-emitting layer contain light-emitting substances emitting light with different colors. Any one of the first light-emitting layer and the second light-emitting layer partly includes a non-formation region (a region where the any one of the first light-emitting layer and the second light-emitting layer is not formed). That is, the light-emitting layer partly includes a region where any the other of the first light-emitting layer and the second light-emitting layer is only formed. A first light emitted from a region of the light-emitting layer where the first light-emitting layer and the second light-emitting layer overlap with each other is different in color from a second light emitted from a region including the non-formation region. The first light and the second light can be obtained from the light-emitting layer at the same time.

Another embodiment of the present invention is a light-emitting element including an EL layer between a pair of electrodes. The EL layer includes a light-emitting layer. The light-emitting layer includes a first light-emitting layer and a second light-emitting layer. The first light-emitting layer and the second light-emitting layer contain light-emitting substances emitting light with different colors. Any one of the first light-emitting layer and the second light-emitting layer partly includes a non-formation region (a region where the any one of the first light-emitting layer and the second light-emitting layer is not formed). That is, the light-emitting layer partly includes a region where any the other of the first light-emitting layer and the second light-emitting layer is only formed. The area of the non-formation region overlapping with the pair of electrodes is greater than or equal to 5% and less than or equal to 95% of an area of a region of the light-emitting layer overlapping with the pair of electrodes. A first light emitted from a region of the light-emitting layer where the first light-emitting layer and the second light-emitting layer overlap with each other is different in color from a second light emitted from a region including the non-formation region. The first light and the second light can be obtained from the light-emitting layer at the same time.

Another embodiment of the present invention is a light-emitting element including an EL layer between a pair of electrodes. The EL layer includes a light-emitting layer. The light-emitting layer includes a first light-emitting layer and a second light-emitting layer. The first light-emitting layer partly includes a non-formation region (a region where the first light-emitting layer is not formed). That is, the light-emitting layer partly includes a region where any the other of the first light-emitting layer and the second light-emitting layer is only formed. The area of the non-formation region overlapping with the pair of electrodes is greater than or equal to 5% and less than or equal to 95% of an area of a region of the light-emitting layer overlapping with the pair of electrodes. A first light emitted from a region of the light-emitting layer where the first light-emitting layer and the second light-emitting layer overlap with each other is different in color from a second light emitted from a region including the non-formation region. The first light and the second light can be obtained from the light-emitting layer at the same time.

Another embodiment of the present invention is a light-emitting element including an EL layer between a pair of electrodes. The EL layer includes a light-emitting layer. The light-emitting layer includes a first light-emitting layer and a second light-emitting layer. The first light-emitting layer partly includes a non-formation region (a region where the first light-emitting layer is not formed). That is, the light-emitting layer partly includes a region where any the other of the first light-emitting layer and the second light-emitting layer is only formed. Light emitted from the light-emitting layer includes a first emission spectrum obtained from a region where the first light-emitting layer and the second light-emitting layer overlap with each other and a second emission spectrum obtained from the second light-emitting layer.

Another embodiment of the present invention is a light-emitting element including an EL layer between a pair of electrodes. The EL layer includes a light-emitting layer. The light-emitting layer includes a first light-emitting layer and a second light-emitting layer. The first light-emitting layer partly includes a non-formation region (a region where the first light-emitting layer is not formed). That is, the light-emitting layer partly includes a region where any the other of the first light-emitting layer and the second light-emitting layer is only formed. The area of the non-formation region overlapping with the pair of electrodes is greater than or equal to 5% and less than or equal to 95% of an area of a region of the light-emitting layer overlapping with the pair of electrodes. Light emitted from the light-emitting layer includes a first emission spectrum obtained from a region where the first light-emitting layer and the second light-emitting layer overlap with each other and a second emission spectrum obtained from the second light-emitting layer.

In any of the above structures, the first emission spectrum has a peak in the range of 500 nm to 650 nm, and the second emission spectrum has a peak in the range of 400 nm to 500 nm.

Another embodiment of the present invention is a light-emitting element including an EL layer between a pair of electrodes. The EL layer includes a light-emitting layer. The light-emitting layer includes a first light-emitting layer and a second light-emitting layer. The first light-emitting layer emits phosphorescence and the second light-emitting layer emits fluorescence. Any one of the first light-emitting layer and the second light-emitting layer partly includes a non-formation region (a region where the any one of the first light-emitting layer and the second light-emitting layer is not formed). That is, the light-emitting layer partly includes a region where any the other of the first light-emitting layer and the second light-emitting layer is only formed. A first light emitted from a region of the light-emitting layer where the first light-emitting layer and the second light-emitting layer overlap with each other is different in color from a second light emitted from a region including the non-formation region. The first light and the second light can be obtained from the light-emitting layer at the same time.

Another embodiment of the present invention is a light-emitting element including an EL layer between a pair of electrodes. The EL layer includes a light-emitting layer. The light-emitting layer includes a first light-emitting layer and a second light-emitting layer. The first light-emitting layer emits phosphorescence and the second light-emitting layer emits fluorescence. Any one of the first light-emitting layer and the second light-emitting layer partly includes a non-formation region (a region where the any one of the first light-emitting layer and the second light-emitting layer is not formed). That is, the light-emitting layer partly includes a region where any the other of the first light-emitting layer and the second light-emitting layer is only formed. The area of the non-formation region overlapping with the pair of electrodes is greater than or equal to 5% and less than or equal to 95% of an area of a region of the light-emitting layer overlapping with the pair of electrodes. A first light emitted from a region of the light-emitting layer where the first light-emitting layer and the second light-emitting layer overlap with each other is different in color from a second light emitted from a region including the non-formation region. The first light and the second light can be obtained from the light-emitting layer at the same time.

Another embodiment of the present invention is a light-emitting element including an EL layer between a pair of electrodes. The EL layer includes a light-emitting layer. The light-emitting layer includes a first light-emitting layer and a second light-emitting layer. The first light-emitting layer emits phosphorescence and the second light-emitting layer emits fluorescence. The first light-emitting layer includes a layer in which an exciplex is formed. Any one of the first light-emitting layer and the second light-emitting layer partly includes a non-formation region (a region where the any one of the first light-emitting layer and the second light-emitting layer is not formed). That is, the light-emitting layer partly includes a region where any the other of the first light-emitting layer and the second light-emitting layer is only formed. A first light emitted from a region of the light-emitting layer where the first light-emitting layer and the second light-emitting layer overlap with each other is different in color from a second light emitted from a region including the non-formation region. The first light and the second light can be obtained from the light-emitting layer at the same time.

Another embodiment of the present invention is a light-emitting element including an EL layer between a pair of electrodes. The EL layer includes at least a light-emitting layer. The light-emitting layer includes at least a first light-emitting layer emitting phosphorescence and a second light-emitting layer emitting fluorescence. The first light-emitting layer includes a layer in which an exciplex is formed. Any one of the first light-emitting layer and the second light-emitting layer partly includes a non-formation region (a region where the any one of the first light-emitting layer and the second light-emitting layer is not formed). That is, the light-emitting layer partly includes a region where any the other of the first light-emitting layer and the second light-emitting layer is only formed. The area of the non-formation region overlapping with the pair of electrodes is greater than or equal to 5% and less than or equal to 95% of an area of a region of the light-emitting layer overlapping with the pair of electrodes. A first light emitted from a region of the light-emitting layer where the first light-emitting layer and the second light-emitting layer overlap with each other is different in color from a second light emitted from a region including the non-formation region. The first light and the second light can be obtained from the light-emitting layer at the same time.

Another embodiment of the present invention is a light-emitting element including an EL layer between a pair of electrodes. The EL layer includes at least a light-emitting layer. The light-emitting layer includes at least a first light-emitting layer emitting phosphorescence and a second light-emitting layer emitting fluorescence. The second light-emitting layer includes a fluorescent substance and a host material having a T1 level lower than that of the fluorescent substance. Any one of the first light-emitting layer and the second light-emitting layer partly includes a non-formation region (a region where the any one of the first light-emitting layer and the second light-emitting layer is not formed). That is, the light-emitting layer partly includes a region where any the other of the first light-emitting layer and the second light-emitting layer is only formed. A first light emitted from a region of the light-emitting layer where the first light-emitting layer and the second light-emitting layer overlap with each other is different in color from a second light emitted from a region including the non-formation region. The first light and the second light can be obtained from the light-emitting layer at the same time.

Another embodiment of the present invention is a light-emitting element including an EL layer between a pair of electrodes. The EL layer includes at least a light-emitting layer. The light-emitting layer includes at least a first light-emitting layer emitting phosphorescence and a second light-emitting layer emitting fluorescence. The second light-emitting layer includes a fluorescent substance and a host material having a T1 level lower than that of the fluorescent substance. Any one of the first light-emitting layer and the second light-emitting layer partly includes a non-formation region (a region where the any one of the first light-emitting layer and the second light-emitting layer is not formed). That is, the light-emitting layer partly includes a region where any the other of the first light-emitting layer and the second light-emitting layer is only formed. The area of the non-formation region overlapping with the pair of electrodes is greater than or equal to 5% and less than or equal to 95% of an area of a region of the light-emitting layer overlapping with the pair of electrodes. A first light emitted from a region of the light-emitting layer where the first light-emitting layer and the second light-emitting layer overlap with each other is different in color from a second light emitted from a region including the non-formation region. The first light and the second light can be obtained from the light-emitting layer at the same time.

In any of the above structures, the first light-emitting layer emits an yellow-orange light and the second light-emitting layer emits a blue light.

In any of the above structures, the first light-emitting layer includes a stack of a layer containing a green-light-emitting substance and a layer containing an orange-light-emitting substance.

In any of the above structures, the first light-emitting layer contains a phosphorescent substance and the second light-emitting layer contains a fluorescent substance.

Another embodiment of the present invention is a light-emitting device including the light-emitting element having any of the aforementioned structures.

The category of one embodiment of the present invention includes not only a light-emitting device including the light-emitting element but also an electronic device and a lighting device each including the light-emitting device. In addition, the light-emitting device might include any of the following modules in its category: a module in which a connector such as a flexible printed circuit (FPC) or a tape carrier package (TCP) is attached to a light-emitting device; a module having a TCP provided with a printed wiring board at the end thereof; and a module having an integrated circuit (IC) directly mounted on a light-emitting element by a chip on glass (COG) method.

According to one embodiment of the present invention, a light-emitting element capable of emitting white light can be provided. According to one embodiment of the present invention, a low-power-consumption light-emitting device including the light-emitting element can also be provided. Furthermore, according to one embodiment of the present invention, low-power consumption electronic device and lighting device each including the light-emitting element can be provided. In addition, according to one embodiment of the present invention, a novel light-emitting element, a novel light-emitting device, a novel lighting device, or the like can be provided. Note that the description of these effects does not disturb the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

In the accompanying drawings:

FIGS. 1A and 1B each illustrate a structure of a light-emitting element of one embodiment of the present invention;

FIGS. 2A and 2B illustrate a light-emitting device;

FIGS. 3A to 3D, 3D′1, and 3D′2 illustrate electronic devices;

FIG. 4 illustrates lighting devices;

FIGS. 5A and 5B illustrate structures of light-emitting elements 1 to 4;

FIGS. 6A to 6D illustrate structures of a light-emitting element of one embodiment of the present invention;

FIGS. 7A and 7B illustrate a structure of a light-emitting element; and

FIG. 8 shows emission spectra of the light-emitting elements 1 to 4.

### DETAILED DESCRIPTION OF THE INVENTION

Embodiments of the present invention will be described in detail with reference to the drawings. However, the present invention is not limited to the description below, and modes and details disclosed herein can be modified in various ways without departing from the purpose and the scope of the present invention. Accordingly, the present invention should not be construed as being limited to description of the embodiments below.

### Embodiment 1

In this embodiment, a light-emitting element of one embodiment of the present invention will be described.

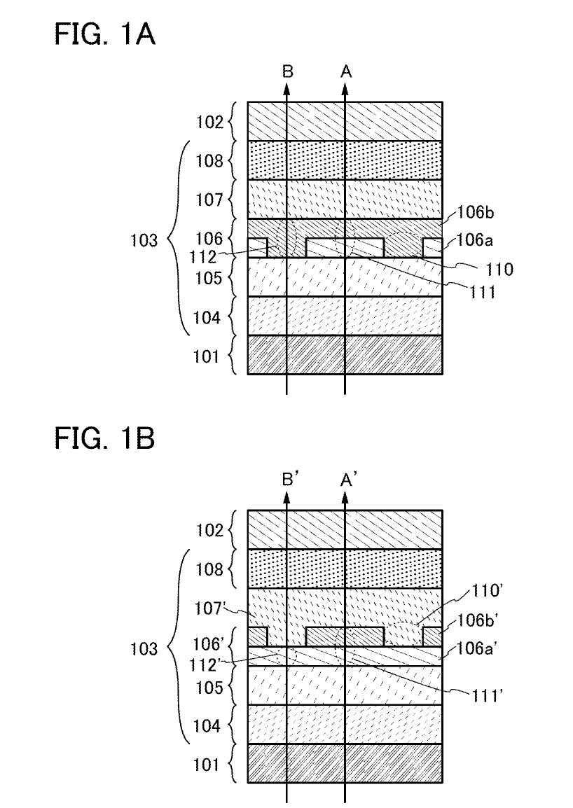

In the light-emitting element of one embodiment of the present invention, an EL layer including a light-emitting layer is provided between a pair of electrodes. The light-emitting layer has a structure in which a first light-emitting layer and a second light-emitting layer containing different light-emitting substances are stacked. In addition, any one of the first light-emitting layer and the second light-emitting layer includes a region where no light-emitting layer is formed (a non-formation region). A structure of the light-emitting element of one embodiment of the present invention will be described in detail below with reference to FIGS. 1A and 1B.

In the light-emitting element illustrated in FIG. 1A, an EL layer 103 including a light-emitting layer 106 is provided between a pair of electrodes (a first electrode 101 and a second electrode 102). In the case where the first electrode 101 is an anode, the EL layer 103 has a structure in which a hole-injection layer 104, a hole-transport layer 105, a light-emitting layer 106, an electron-transport layer 107, an electron-injection layer 108, and the like are stacked in this order over the first electrode 101. The light-emitting layer 106 has a structure in which a first light-emitting layer 106a and a second light-emitting layer 106b are stacked. In part of the first light-emitting layer 106a, a region 110 where the first light-emitting layer 106a is not formed (a non-formation region) is provided. Note that in that case, the second light-emitting layer 106b is formed in the non-formation region of the first light-emitting layer 106a as well as over the first light-emitting layer 106a.

In FIG. 1A, a region 111 in the light-emitting layer 106 has a structure in which the first light-emitting layer 106a and the second light-emitting layer 106b are stacked; hence, light having a first emission spectrum is emitted in the direction of an arrow A. A region 112 in the light-emitting layer 106 includes only the second light-emitting layer 106b, so that light having a second emission spectrum, which is different from the first emission spectrum, is emitted in the direction of an arrow B. In other words, the light emission spectrum of the light-emitting layer 106 depends on whether the non-formation region exists. Therefore, a change in the proportion of the non-formation region in the light-emitting layer 106 allows the correlated color temperature (or chromaticity) of a mixed color including plural emission spectra in one light-emitting element (or one pixel) to be controlled in a desired range. Note that the proportion (the area ratio) of the non-formation region in the light-emitting layer 106 is preferably greater than or equal to 5% and less than or equal to 95%. Note that the desired range of the correlated color temperature in this specification is the range defined by Japanese Industrial Standards (JIS) (2600 K to 7100 K), and is preferably the range of incandescent light (2600 K to 3250 K) or warm white light (3250 K to 3800 K).

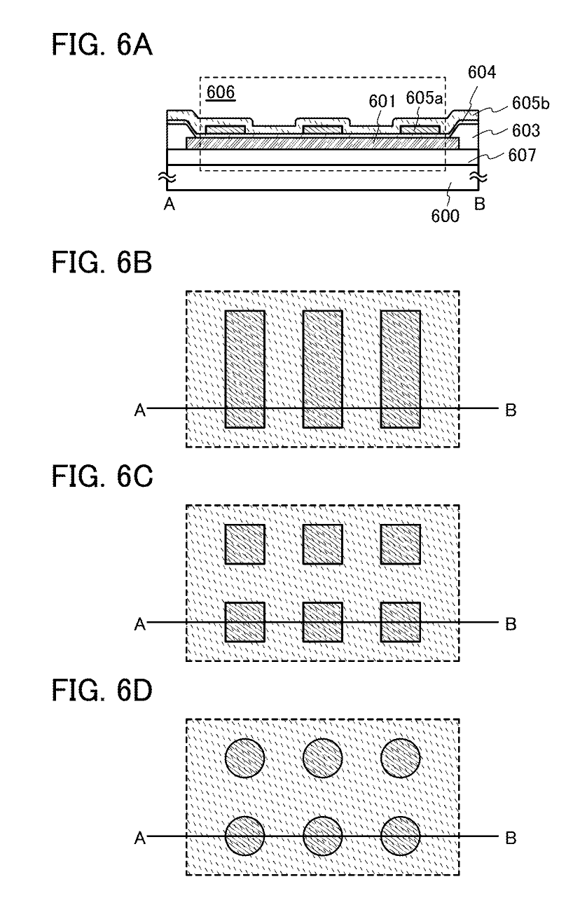

FIG. 6A is an example of a cross-sectional view of the structure of the light-emitting layer included in the EL layer of the light-emitting element illustrated in FIGS. 1A and 1B. In FIG. 6A, a first electrode (anode) 601 is formed over a substrate 600 with an element formation layer 607 positioned therebetween, and an edge portion of the first electrode (anode) 601 is covered with an insulator 603. Furthermore, a stack 604 including a hole-injection layer and a hole-transport layer is formed over the first electrode (anode) 601, and a first light-emitting layer 605a is formed thereover. The first light-emitting layer 605a is formed by an evaporation method using a mask, and therefore a region where the first light-emitting layer 605a is not formed (non-formation region) is provided on the same plane. Over the first light-emitting layer 605a, a second light-emitting layer 605b is formed without using a mask. Thus, the second light-emitting layer 605b is formed not only over the first light-emitting layer 605a but also over the stack 604 including the hole-injection layer and the hole-transport layer, i.e., in the non-formation region of the first light-emitting layer 605a. Such a structure in which a plurality of first light-emitting layers 605a are formed over the first electrode (anode) 601 having a continuous plane is a distinctive structure of one embodiment of the present invention. Note that the element formation layer 607 illustrated in FIG. 6A, which includes a field effect transistor (FET) electrically connected to the light-emitting element, is not necessarily provided.

FIGS. 6B, 6C, and 6D are top views of a region 606 surrounded by a dotted line in FIG. 6A. Note that the straight line AB in FIG. 6A corresponds to the straight lines AB in FIGS. 6B to 6D. As illustrated in FIGS. 6B to 6D, the first light-emitting layer 605a can have a variety of structures which depend on the shape of a mask used in evaporation; for example, a substantially rectangular shape illustrated in FIG. 6B, a substantially square shape illustrated in FIG. 6C, a circular shape illustrated in FIG. 6D, a triangular shape, or an elliptical shape. The arrangement of the first light-emitting layer 605a can also be determined as appropriate.

Alternatively, a light-emitting layer 106′ can have a structure in which a first light-emitting layer 106a′ and a second light-emitting layer 106b′ are stacked as illustrated in FIG. 1B; the second light-emitting layer 106b′ including a non-formation region (a region 110′) is formed over the first light-emitting layer 106a′. Note that in that case, an electron-transport layer 107′ is formed in the non-formation region of the second light-emitting layer 106b′ as well as over the second light-emitting layer 106b′.

In the structure illustrated in FIG. 1B, as in the structure illustrated in FIG. 1A, a region 111′ in the light-emitting layer 106′ has a structure in which the first light-emitting layer 106a′ and the second light-emitting layer 106b′ are stacked; hence, light having a first′ emission spectrum is emitted in the direction of an arrow A′. In a region 112′ in the light-emitting layer 106′, light having a second′ emission spectrum is emitted in the direction of an arrow B′. Therefore, a change in the proportion of the non-formation region in the light-emitting layer allows the correlated color temperature (or chromaticity) of a mixed color including plural emission spectra in one light-emitting element (or one pixel) to be controlled in a desired range.

The first light-emitting layer (106a, 106a′) and the second light-emitting layer (106b, 106b′) need to include light-emitting substances (a fluorescent substance or a phosphorescent substance) emitting light with different colors. However, both the first light-emitting layer and the second light-emitting layer may include a fluorescent substance or a phosphorescent substance, or one of them may include a fluorescent substance while the other includes a phosphorescent substance. In addition to such light-emitting substances, an organic compound (e.g., a hole-transport material or an electron-transport material) can also be used as a host material. Furthermore, another kind of organic compound (e.g., a hole-transport material or an electron-transport material) may be used in addition to the host material.

In the case where the light-emitting layer (106, 106′) contains a fluorescent substance and a host material, a triplet exciton of the host material can be efficiently converted into a singlet exciton by triplet-triplet annihilation (TTA), so that light is emitted from the fluorescent substance by energy transfer from the singlet exciton.

Specifically, in the light-emitting layer (106, 106′), the lowest triplet excitation energy level (T1 level) of the host material is preferably lower than that of the fluorescent substance. The proportion of host materials is generally much higher than that of fluorescent substances in the light-emitting layer. When the host material and the fluorescent substance are used in combination such that the T1 level of the host material is lower than that of the fluorescent substance, it is possible to prevent a decrease in the probability of collision between triplet excitons, which is caused when the triplet excitons generated in the light-emitting layer (106, 106′) are trapped by few fluorescent substances (molecules) in the light-emitting layer (106, 106′) and localized, leading to an increase in the probability of TTA. Thus, the emission efficiency of fluorescence of the light-emitting layer 106 can be increased. Note that as the fluorescent substance used in the light-emitting layer (106, 106′), known substances that emit blue light (with an emission spectrum peak in the range of 400 nm to 480 nm), green light (with an emission spectrum peak in the range of 500 nm to 560 nm), red light (with an emission spectrum peak in the range of 580 nm and 680 nm), yellow light (with an emission spectrum peak in the range of 540 nm to 600 nm, including yellow-green to orange), and the like can be used as appropriate.

In the case where the light-emitting layer (106, 106′) contains a phosphorescent substance and a host material, light can be emitted from the phosphorescent substance by energy transfer from a triplet exciton of the host material. When another organic compound is used in addition to the phosphorescent substance and the host material, light can be emitted from the phosphorescent substance by energy transfer from an exciplex, which is formed by the host material and the organic compound. Note that in the case where phosphorescence is obtained by utilizing the energy transfer from the exciplex, the emission wavelength of the exciplex is at a longer side than those (fluorescence wavelengths) of organic compounds forming the exciplex, whereby these emission spectra can be shifted at a longer side. This results in a reduction in driving voltage. In addition, energy can be transferred from the exciplex to the phosphorescent substance, achieving a high emission efficiency. Note that as the phosphorescent substance used in the light-emitting layer (106, 106′), known substances that emit blue light (with an emission spectrum peak in the range of 400 nm to 480 nm), green light (with an emission spectrum peak in the range of 500 nm to 560 nm), red light (with an emission spectrum peak in the range of 580 nm and 680 nm), yellow light (with an emission spectrum peak in the range of 540 nm to 600 nm, including yellow-green to orange), and the like can be used as appropriate.

Examples of the organic compound such as a host material, which is used in combination with the light-emitting substance in the first light-emitting layer (106a, 106a′) and the second light-emitting layer (106b, 106b′) included in the light-emitting layer (106, 106′), include electron-transport materials mainly having an electron mobility of 1×10⁻⁶ cm²/Vs or higher and hole-transport materials mainly having a hole mobility of 1×10⁻⁶ cm²/Vs or higher. Note that for the layers containing the phosphorescent substances in the light-emitting layer (106, 106′), two or more kinds of the above-described organic compounds are selected for each layer such that an exciplex can be formed.

When the light-emitting substance (the fluorescent substance or the phosphorescent substance) is dispersed in the organic compounds in the light-emitting layer (106, 106′), crystallization in the light-emitting layer can be suppressed. Furthermore, such a structure suppresses concentration quenching due to high concentration of the light-emitting substance in the light-emitting layer (106, 106′), increasing the emission efficiency of the light-emitting element.

In the light-emitting layer (106, 106′), the T1 level of the organic compound is preferably higher than that of the phosphorescent substance for the following reason. When the T1 level of the organic compound is lower than that of the phosphorescent substance, the triplet excitation energy of the phosphorescent substance that contributes to light emission is quenched by the organic compound, which leads to a reduction in emission efficiency.

Examples of combinations of colors emitted from the first light-emitting layer (106a, 106a′) and the second light-emitting layer (106b, 106b′) included in the light-emitting layer (106, 106′), which are represented by “emission color of the first light-emitting layer (106a, 106a′)\emission color of the second light-emitting layer (106b, 106b′)”, include “blue\yellow”, “blue\orange•green”, “blue\green•orange”, “blue\yellow•red”, “blue\green•red”, “blue\red•yellow”, “yellow\blue”, “yellow\blue•red”, “yellow\ red•green”, “yellow \blue•orange”, “yellow \red•blue”, “red\blue•green”, “red\green•blue”, “orange•green\blue”, “green•orange\blue”, “yellow•red\blue”, “green•red \blue”, “red•yellow\blue”, “blue•red\yellow”, “red•green\yellow”, “blue•orange\yellow”, “red•blue\yellow”, “blue•green\red”, and “green•blue\red”. Note that the above-described combinations are possible even when the first light-emitting layer (106a, 106a′) and the second light-emitting layer (106b, 106b′) are stacked in reverse order. Note that here, “blue light” has an emission spectrum peak in the range of 400 nm to 480 nm, “green light” has an emission spectrum peak in the range of 500 nm to 560 nm, “red light” has an emission spectrum peak in the range of 580 nm to 680 nm, and “yellow light” or “orange light” has an emission spectrum peak in the range of 540 nm to 600 m.

Note that in the above light-emitting layer (106, 106′), in the case where one of the first light-emitting layer (106a, 106a′) and the second light-emitting layer (106b, 106b′) contains a fluorescent substance and the other contains a phosphorescent substance, an exciplex is preferably formed in the layer containing the phosphorescent substance. The reason for this is as follows. When a fluorescent layer and a phosphorescent layer are stacked, triplet excitation energy generated in the phosphorescent layer is generally transferred to a host material in the fluorescent layer to cause non-radiative decay. In contrast, in the structure in which an exciplex is formed in the phosphorescent layer, the triplet excitation energy is transferred to the phosphorescent substance, so that light emission is obtained. In addition, an exciton is unlikely to be diffused from the exciplex to a substance other than the phosphorescent substance. As a result, such a structure allows phosphoresce as well as fluorescence to be effectively produced from the stacked light-emitting layer (106, 106′).

Next, a specific example for fabrication of the above light-emitting element will be described.

As the first electrode (anode) 101 and the second electrode (cathode) 102, a metal, an alloy, an electrically conductive compound, a mixture thereof, and the like can be used. Specifically, indium oxide-tin oxide (indium tin oxide), indium oxide-tin oxide containing silicon or silicon oxide, indium oxide-zinc oxide (indium zinc oxide), indium oxide containing tungsten oxide and zinc oxide, gold (Au), platinum (Pt), nickel (Ni), tungsten (W), chromium (Cr), molybdenum (Mo), iron (Fe), cobalt (Co), copper (Cu), palladium (Pd), and titanium (Ti) can be used. In addition, an element belonging to Group 1 or Group 2 of the periodic table, that is, an alkali metal such as lithium (Li) or cesium (Cs), an alkaline earth metal such as calcium (Ca) or strontium (Sr), magnesium (Mg), an alloy containing such an element (e.g., MgAg or AlLi), a rare earth metal such as europium (Eu) or ytterbium (Yb), an alloy containing such an element, graphene, and the like can be used. The first electrode (anode) 101 and the second electrode (cathode) 102 can be formed by, for example, a sputtering method or an evaporation method (including a vacuum evaporation method).

The hole-injection layer 104 injects holes into the light-emitting layer (106, 106′) through the hole-transport layer 105 with a high hole-transport property, and includes a hole-transport material and an acceptor substance. That is, the acceptor material and another material are mixed. Note that a film containing only an acceptor material can also serve as the hole-injection layer 104. When the hole-injection layer 104 contains a hole-transport material and an acceptor substance, electrons are extracted from the hole-transport material by the acceptor substance to generate holes and the holes are injected into the light-emitting layer (106, 106′) through the hole-transport layer 105. The hole-transport layer 105 is formed using a hole-transport material. The hole-injection layer 104 and the hole-transport layer 105 can be formed by, for example, a sputtering method or an evaporation method (including a vacuum evaporation method).

Specific examples of the hole-transport material, which is used for the hole-injection layer 104 and the hole-transport layer 105, include aromatic amine compounds such as 4,4′-bis[N-(1-naphthyl)-N-phenylamino]biphenyl (abbreviation: NPB or α-NPD), N,N′-bis(3-methylphenyl)-N,N′-diphenyl-[1,1′-biphenyl]-4,4′-diamine (abbreviation: TPD), 4,4′,4″-tris(carbazol-9-yl)triphenylamine (abbreviation: TCTA), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluoren-2-yl)-N-phenyl amino]biphenyl (abbreviation: BSPB); 3-[N-(9-phenylcarbazol-3-yl)-N-phenylamino]-9-phenylcarbazole (abbreviation: PCzPCA1); 3,6-bis[N-(9-phenylcarbazol-3-yl)-N-phenylamino]-9-phenylcarbazole (abbreviation: PCzPCA2); and 3-[N-(1-naphthyl)-N-(9-phenylcarbazol-3-yl)amino]-9-phenylcarbazole (abbreviation: PCzPCN1). Other examples include carbazole derivatives such as 4,4′-di(N-carbazolyl)biphenyl (abbreviation: CBP), 1,3,5-tris[4-(N-carbazolyl)phenyl]benzene (abbreviation: TCPB), and 9-[4-(10-phenyl-9-anthracenyl)phenyl]-9H-carbazole (abbreviation: CzPA). The substances listed here are mainly ones that have a hole mobility of 1×10⁻⁶ cm²/Vs or higher. Note that any substance other than the substances listed here may be used as long as the hole-transport property is higher than the electron-transport property.

Other examples include high molecular compounds such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), and poly[N,N-bis(4-butylphenyl)-N,N-bis(phenyl)benzidine] (abbreviation: Poly-TPD).

Examples of the acceptor substance that is used in the hole-injection layer 104 include oxides of metals belonging to Groups 4 to 8 of the periodic table. Specifically, molybdenum oxide is particularly preferable. Other examples of the acceptor material include compounds having an electron-withdrawing group (a halogen group or a cyano group) such as 7,7,8,8-tetracyano-2,3,5,6-tetrafluoroquinodimethane (abbreviation: F₄-TCNQ), chloranil, and 2,3,6,7,10,11-hexacyano-1,4,5,8,9,12-hexaazatriphenylene (HAT-CN). In particular, a compound in which electron-withdrawing groups are bonded to a condensed aromatic ring having a plurality of hetero atoms, like HAT-CN, is thermally stable and preferable.

The light-emitting layer (106, 106′), which includes a stack of the first light-emitting layer (106a, 106a′) and the second light-emitting layer (106b, 106b′), can be formed by, for example, a sputtering method or an evaporation method (including a vacuum evaporation method). Note that, when the light-emitting layer including a non-formation region is formed, part of the light-emitting layer is not formed so that the non-formation region is formed in one of the first light-emitting layer (106a, 106a′) and the second light-emitting layer (106b, 106b′). A non-formation region can be formed partly in the light-emitting layer with use of, for example, a mask that allows the formation of a desired pattern (a grid-like pattern, a ring-like pattern). The other light-emitting layer that does not include the non-formation region is formed without using a mask or the like.

Examples of the fluorescent substance used in the light-emitting layer (106, 106′) include the following substances that convert singlet excitation energy into light emission.

Examples of the fluorescent substance include N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2P CABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), and 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM). Condensed aromatic diamine compounds typified by pyrenediamine compounds such as N,N′-bis[4-(9-phenyl-9H-fluoren-9-yl)phenyl]-N,N′-diphenylpyrene-1,6-diamine (abbreviation: 1,6FLPAPrn) and N,N′-bis(3-methylphenyl)-N,N′-bis[3-(9-phenyl-9H-fluoren-9-yl)phenyl]pyrene-1,6-diamine (abbreviation: 1,6mMemFLPAPrn) are particularly preferable because of their high hole-trapping properties, high emission efficiency, and high reliability.

Examples of the phosphorescent substance used in the light-emitting layer (106, 106′) include the following substances that convert triplet excitation energy into light emission.

The examples include bis[2-(3′,5′-bistrifluoromethyl-phenyl)-pyridinato-N,C^{2′}]iridium(III) picolinate (abbreviation: [Ir(CF₃ppy)₂(pic)]), bis[2-(4′,6′-difluorophenyl)pyridinato-N, C^{2′}]iridium(III) acetylacetonate (abbreviation: FIracac), tris(2-phenylpyridinato)iridium(III) (abbreviation: [Ir(ppy)₃]), bis(2-phenylpyridinato)iridium(III) acetylacetonate (abbreviation: [Ir(ppy)₂(acac)]), tris(acetylacetonato) (monophenanthroline)terbium(III) (abbreviation: [Tb(acac)₃(Phen)]), bis(benzo[h]quinolinato)iridium (III) acetylacetonate (abbreviation: [Ir(bzq)₂(acac)]), bis(2,4-diphenyl-1,3-oxazolato-N,C^{2′})iridium(III) acetylacetonate (abbreviation: [Ir(dpo)₂(acac)]), bis {2-[4′-(perfluorophenyl)phenyl]pyridinato-N,C^{2′}}iridium(III) acetylacetonate (abbreviation: [Ir(p-PF-ph)₂(acac)]), bis(2-phenylbenzothiazolato-N,C^{2′})iridium(III) acetylacetonate (abbreviation: [Ir(bt)₂(acac)]), bis[2-(2′-benzo[4,5-α]thienyl)pyridinato-N,C^{3′}]iridium(III) acetylacetonate (abbreviation: [Ir(btp)₂(acac)]), bis(1-phenylisoquinolinato-N,C^{2′})iridium(III) acetylacetonate (abbreviation: [Ir(piq)₂(acac)]), (acetylacetonato)bis[2,3-bis(4-fluorophenyl)quinoxalinato]iridium(III) (abbreviation: [Ir(Fdpq)₂(acac)]), (acetylacetonato)bis(3,5-dimethyl-2-phenylpyrazinato)iridium(III) (abbreviation: [Ir(mppr-Me)₂(acac)]), (acetylacetonato)bis(5-isopropyl-3-methyl-2-phenylpyrazinato)iridium(III) (abbreviation: [Ir(mppr-iPr)₂(acac)]), (acetylacetonato)bis (2,3,5-triphenylpyrazinato)iridium(III) (abbreviation: [Ir(tppr)₂(acac)]), bis (2,3,5-triphenylpyrazinato) (dipivaloylmethanato)iridium(III) (abbreviation: [Ir(tppr)₂(dpm)], (acetylacetonato)bis(6-tert-butyl-4-phenylpyrimidinato)iridium(III) (abbreviation: [Ir(tBuppm)₂(acac)]), (acetylacetonato)bis(4,6-diphenylpyrimidinato)iridium(III) (abbreviation: [Ir(dppm)₂(acac)]), 2,3,7,8,12,13,17,18-octaethyl-21H,23H-porphyrin platinum(II) (abbreviation: PtOEP), tris (1,3-diphenyl-1,3-propanedionato) (monophenanthroline)europium(III) (abbreviation: [Eu(DBM)₃(Phen)]), and tris[1-(2-thenoyl)-3,3,3-trifluoroacetonato] (monophenanthroline)europium(III) (abbreviation: [Eu(TTA)₃(Phen)]).

Note that a thermally activated delayed fluorescence (TADF) material that exhibits thermally activated delayed fluorescence can be used instead of the phosphorescent substances. Note that “delayed fluorescence” exhibited by the TADF material refers to light emission having the same emission spectrum as normal fluorescence and an extremely long lifetime. The lifetime is 10⁻⁶ seconds or longer, preferably 10⁻³ seconds or longer.

Specific examples of the TADF material include fullerene, a derivative thereof, an acridine derivative such as proflavine, and eosin. Other examples include a metal-containing porphyrin, such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP). Alternatively, a heterocyclic compound including a π-electron rich heteroaromatic ring and a π-electron deficient heteroaromatic ring can be used, such as 2-(biphenyl-4-yl)-4,6-bis(12-phenylindolo[2,3-a]carbazol-11-yl)-1,3,5-triazine (PIC-TRZ). Note that a material in which the π-electron rich heteroaromatic ring is directly bonded to the π-electron deficient heteroaromatic ring is particularly preferably used because both the donor property of the π-electron rich heteroaromatic ring and the acceptor property of the π-electron deficient heteroaromatic ring are increased and the energy difference between the S1 level and the T1 level is reduced.

In the case where the light-emitting layer (106, 106′) contains a fluorescent substance, any of the following organic compounds is preferably used as a host material: anthracene compounds such as 9-phenyl-3-[4-(10-phenyl-9-anthryl)phenyl]-9H-carbazole (abbreviation: PCzPA), 3-[4-(1-naphthyl)-phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), and 9-phenyl-10-{4-(9-phenyl-9H-fluoren-9-yl)biphenyl-4′-yl}anthracene (abbreviation: FLPPA). Note that the use of a substance having an anthracene skeleton as the host material offers a light-emitting layer that has high emission efficiency and durability. In particular, CzPA, cgDBCzPA, 2mBnfPPA, and PCzPA are preferable because of their excellent characteristics.

As the electron-transport organic compound (electron-transport material) used for the light-emitting layer (106, 106′), a π-electron deficient heteroaromatic compound such as a nitrogen-containing heteroaromatic compound is preferable, examples of which include 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), and 6-[3-(dibenzothiophen-4-yl)phenyl]dibenzo[f,h]quinoxaline (abbreviation: 6mDBTPDBq-II).

As the hole-transport organic compound (hole-transport material) used for the light-emitting layer (106, 106′), a π-electron rich heteroaromatic compound (e.g., a carbazole derivative or an indole derivative) or an aromatic amine compound is preferable, examples of which include 4-phenyl-4′-(9-phenyl-9H-carbazol-3-yl)triphenylamine (abbreviation: PCBA1BP), 4,4′-di(1-naphthyl)-4″-(9-phenyl-9H-carbazol-3-yl)triphenylamine (abbreviation: PCBNBB), 3-[N-(1-naphthyl)-N-(9-phenylcarbazol-3-yl)amino]-9-phenylcarbazole (abbreviation: PCzPCN1), 4,4′,4″-tris[N-(1-naphthyl)-N-phenylamino]triphenylamine (abbreviation: 1′-TNATA), 2,7-bis[N-(4-diphenylaminophenyl)-N-phenylamino]-spiro-9,9′-bifluorene (abbreviation: DPA2SF), N,N-bis(9-phenylcarbazol-3-yl)-N,N′-diphenylbenzene-1,3-diamine (abbreviation: PCA2B), N-(9,9-dimethyl-2-diphenylamino-9H-fluoren-7-yl)diphenylamine (abbreviation: DPNF), N,N′,N″-triphenyl-N,N′,N″-tris(9-phenylcarbazol-3-yl)benzene-1,3,5-triamine (abbreviation: PCA3B), 2-[N-(9-phenylcarbazol-3-yl)-N-phenylamino]spiro-9,9′-bifluorene (abbreviation: PCASF), 2-[N-(4-diphenylaminophenyl)-N-phenylamino]spiro-9,9′-bifluorene (abbreviation: DPASF), N,N′-bis[4-(carbazol-9-yl)phenyl]-N,N′-diphenyl-9,9-dimethylfluorene-2,7-diamine (abbreviation: YGA2F), 4,4′-bis[N-(3-methylphenyl)-N-phenylamino]biphenyl (abbreviation: TPD), 4,4′-bis[N-(4-diphenylaminophenyl)-N-phenylamino]biphenyl (abbreviation: DPAB), N-(9,9-dimethyl-9H-fluoren-2-yl)-N-{9,9-dimethyl-2-[N′-phenyl-N′-(9,9-dimethyl-9H-fluoren-2-yl)amino]-9H-fluoren-7-yl}phenylamine (abbreviation: DFLADFL), 3-[N-(9-phenylcarbazol-3-yl)-N-phenylamino]-9-phenylcarbazole (abbreviation: PCzPCA1), 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 4,4′-bis(N-{4-[N′-(3-methylphenyl)-N-phenylamino]phenyl}-N-phenylamino)biphenyl (abbreviation: DNTPD), 3,6-bis[N-(4-diphenylaminophenyl)-N-(1-naphthyl)amino]-9-phenylcarbazole (abbreviation: PCzTPN2), and 3,6-bis[N-(9-phenylcarbazol-3-yl)-N-phenylamino]-9-phenylcarbazole (abbreviation: PCzPCA2).

The electron-transport layer (107, 107′) is a layer that contains a substance having a high electron-transport property. For the electron-transport layer (107, 107′), it is possible to use a metal complex such as Alga, tris(4-methyl-8-quinolinolato)aluminum (abbreviation: Almq₃), bis(10-hydroxybenzo[h]quinolinato)beryllium (abbreviation: BeBq₂), BAlq, Zn(BOX)₂, and bis[2-(2-hydroxyphenyl)benzothiazolato]zinc (abbreviation: Zn(BTZ)₂). A heteroaromatic compound such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazol-2-yl)stilbene (abbreviation: BzOs) can also be used. A high molecular compound such as poly(2,5-pyridinediyl) (abbreviation: PPy), poly[(9,9-dihexylfluorene-2,7-diyl)-co-(pyridine-3,5-diyl)] (abbreviation: PF-Py) and poly[(9,9-dioctylfluorene-2,7-diyl)-co-(2,2′-bipyridine-6,6′-diyl)] (abbreviation: PF-BPy) can also be used. The substances listed here are mainly ones that have an electron mobility of 1×10⁻⁶ cm²/Vs or higher. Note that any substance other than the substances listed here may be used for the electron-transport layer (107, 107′) as long as the electron-transport property is higher than the hole-transport property.

The electron-transport layer (107, 107′) is not limited to a single layer, but may be a stack of two or more layers each containing any of the substances listed above.

The electron-injection layer 108 is a layer that contains a substance having a high electron-injection property. For the electron-injection layer 108, an alkali metal, an alkaline earth metal, or a compound thereof such as lithium fluoride (LiF), cesium fluoride (CsF), calcium fluoride (CaF₂), or lithium oxide (LiOₓ) can be used. A rare earth metal compound like erbium fluoride (ErF₃) can also be used. An electride may also be used for the electron-injection layer 108. Examples of the electride include a substance in which electrons are added at high concentration to calcium oxide-aluminum oxide. Any of the substances for forming the electron-transport layer (107, 107′), which are listed above, can also be used.

A composite material in which an organic compound and an electron donor (donor) are mixed may also be used for the electron-injection layer 108. The composite material is superior in an electron-injection property and an electron-transport property, because electrons are generated in the organic compound by the electron donor. In that case, the organic compound is preferably a material that is excellent in transporting the generated electrons. Specifically, for example, the substances for forming the electron-transport layer (107, 107′) (e.g., a metal complex or a heteroaromatic compound), which are given above, can be used. As the electron donor, a substance showing an electron-donating property with respect to the organic compound may be used. Specifically, an alkali metal, an alkaline earth metal, and a rare earth metal are preferable, and lithium, cesium, magnesium, calcium, erbium, and ytterbium are given. In addition, an alkali metal oxide or an alkaline earth metal oxide is preferable, and lithium oxide, calcium oxide, and barium oxide are given. A Lewis base such as magnesium oxide can also be used. An organic compound such as tetrathiafulvalene (abbreviation: TTF) can also be used.

Note that each of the hole-injection layer 104, the hole-transport layer 105, the light-emitting layer (106, 106′) (the first light-emitting layer (106a, 106a′) and the second light-emitting layer (106b, 106b′)), the electron-transport layer (107, 107′), and the electron-injection layer 108 can be formed by a method such as an evaporation method (e.g., a vacuum evaporation method), an ink-jet method, or a coating method.

In the above-described light-emitting element, carriers are injected because of a potential difference generated between the first electrode 101 and the second electrode 102, and the holes and the electrons are recombined in the EL layer 103, whereby light is emitted. Then, the emitted light is extracted outside through one or both of the first electrode 101 and the second electrode 102. Thus, one or both of the first electrode 101 and the second electrode 102 are electrodes having light-transmitting properties.

In the light-emitting element having the structure described in this embodiment, the intensity of light from the light-emitting layer can be changed for each color, whereby a desired white light can be emitted from the whole light-emitting element.

Note that the structure described in this embodiment can be combined as appropriate with any of the structures described in the other embodiments.

### Embodiment 2

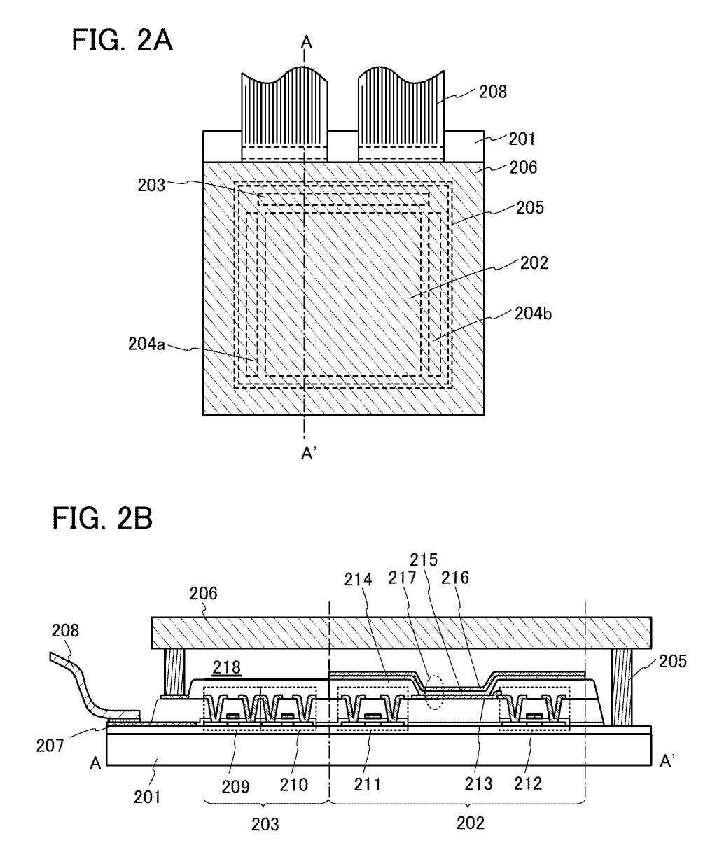

In this embodiment, as an example of a light-emitting device including the light-emitting element of one embodiment of the present invention, an active matrix light-emitting device is described with reference to FIGS. 2A and 2B. Note that the light-emitting element described in Embodiment 1 can be used for the light-emitting device described in this embodiment.

FIG. 2A is a top view illustrating the light-emitting device and FIG. 2B is a cross-sectional view taken along the dashed line A-A′ in FIG. 2A. The active matrix light-emitting device of this embodiment includes, over an element substrate 201, a pixel portion 202, a driver circuit portion (a source line driver circuit) 203, and driver circuit portions (gate line driver circuits) 204 (204a and 204b). The pixel portion 202, the driver circuit portion 203, and the driver circuit portions 204 are sealed between the element substrate 201 and a sealing substrate 206 with a sealant 205.

In addition, over the element substrate 201, a lead wiring 207 for connecting an external input terminal that transmits a signal (e.g., a video signal, a clock signal, a start signal, or a reset signal) or an electric potential to the driver circuit portion 203 and the driver circuit portions 204 is provided. Here, as an example, a flexible printed circuit (FPC) 208 is provided as the external input terminal. Although only the FPC is illustrated here, the FPC may be provided with a printed wiring board (PWB). The light-emitting device in this specification includes, in its category, not only the light-emitting device itself but also the light-emitting device provided with the FPC or the PWB.

Next, a cross-sectional structure is described with reference to FIG. 2B. The driver circuit portions and the pixel portion are formed over the element substrate 201; the driver circuit portion 203 that is the source line driver circuit and the pixel portion 202 are illustrated here.

In the driver circuit portion 203, an FET 209 and an FET 210 are combined as an example. Note that each of the FET 209 and the FET 210 included in the driver circuit portion 203 may be formed with a circuit including transistors having the same conductivity type (either an n-channel transistor or a p-channel transistor) or a CMOS circuit including an n-channel transistor and a p-channel transistor. Although a driver integrated type in which the driver circuit is formed on the substrate is described in this embodiment, the driver circuit may not necessarily be formed on the substrate, and may be formed outside the substrate.

The pixel portion 202 includes a plurality of pixels each of which includes a switching FET 211, a current control FET 212, and a first electrode (anode) 213 that is electrically connected to a wiring (a source electrode or a drain electrode) of the current control FET 212. In this embodiment, the pixel portion 202 includes two FETs, the switching FET 211 and the current control FET 212; however, one embodiment of the present invention is not limited thereto. The pixel portion 202 may include, for example, three or more FETs and a capacitor in combination.

As the FETs 209, 210, 211, and 212, for example, a staggered transistor or an inverted staggered transistor can be used. Examples of a semiconductor material that can be used for the FETs 209, 210, 211, and 212 include Group 13 semiconductors (e.g., gallium), Group 14 semiconductors (e.g., silicon), compound semiconductors, oxide semiconductors, and organic semiconductors. In addition, there is no particular limitation on the crystallinity of a film including the semiconductor material, and an amorphous semiconductor film or a crystalline semiconductor film can be used. In particular, an oxide semiconductor is preferably used for the FETs 209, 210, 211, and 212. Examples of the oxide semiconductor include an In—Ga oxide and an In-M-Zn oxide (M is Al, Ga, Y, Zr, La, Ce, or Nd). For example, an oxide semiconductor material that has an energy gap of 2 eV or more, preferably 2.5 eV or more, further preferably 3 eV or more is used for the FETs 209, 210, 211, and 212, so that the off-state current of the transistors can be reduced.

An insulator 214 is formed to cover edge portions of the first electrode 213. In this embodiment, the insulator 214 is formed using a positive photosensitive acrylic resin. The first electrode 213 is used as an anode in this embodiment.

The insulator 214 preferably has a curved surface with curvature at an upper end portion or a lower end portion thereof. This offers a good coverage of the insulator 214 with a film to be formed thereover. The insulator 214 can be formed using, for example, either a negative photosensitive resin or a positive photosensitive resin. The material of the insulator 214 is not limited to an organic compound and an inorganic compound such as silicon oxide, silicon oxynitride, or silicon nitride can also be used.

An EL layer 215 and a second electrode (cathode) 216 are stacked over the first electrode (anode) 213. The EL layer 215 includes at least a light-emitting layer, and the light-emitting layer has the stacked-layer structure described in Embodiment 1. In the EL layer 215, a hole-injection layer, a hole-transport layer, an electron-transport layer, an electron-injection layer, a charge-generation layer, and the like can be provided as appropriate in addition to the light-emitting layer.

A light-emitting element 217 is formed of a stack of the first electrode (anode) 213, the EL layer 215, and the second electrode (cathode) 216. For the first electrode (anode) 213, the EL layer 215, and the second electrode (cathode) 216, any of the materials listed in Embodiment 1 can be used. Although not illustrated, the second electrode (cathode) 216 is electrically connected to the FPC 208 that is an external input terminal.

Although the cross-sectional view of FIG. 2B illustrates only one light-emitting element 217, a plurality of light-emitting elements including the light-emitting element of one embodiment of the present invention are arranged in matrix in the pixel portion 202. Light-emitting elements that emit light of three kinds of colors (R, G, and B) are selectively formed in the pixel portion 202, whereby a light-emitting device capable of full color display can be obtained. In addition to the light-emitting elements that emit light of three kinds of colors (R, G, and B), for example, a light-emitting element that emits light of white (W), yellow (Y), magenta (M), cyan (C), or the like may be provided so as to obtain elements emitting light of four kinds of colors ((R, G, B, and W), (R, G, B, and Y), (R, G, B, and M), or (R, G, B, and C)). The addition of such elements emitting light of plural kinds of colors produces effects such as improved color purity and reduced power consumption. A micro optical resonator (microcavity) structure in which a light resonant effect between electrodes is utilized may be employed in order to narrow a line width of each emission color. A light-emitting device that is capable of full color display may also be fabricated by a combination with color filters. Furthermore, the light-emitting element of one embodiment of the present invention may be combined with a tandem structure.

Furthermore, the sealing substrate 206 is attached to the element substrate 201 with the sealant 205, whereby a light-emitting element 217 is provided in a space 218 surrounded by the element substrate 201, the sealing substrate 206, and the sealant 205. The space 218 may be filled with an inert gas (such as nitrogen or argon), or the sealant 205.

An epoxy-based resin or glass frit is preferably used for the sealant 205. The material preferably allows as little moisture and oxygen as possible to penetrate. As the sealing substrate 206, a glass substrate, a quartz substrate, or a plastic substrate formed of fiber-reinforced plastic (FRP), polyvinyl fluoride) (PVF), polyester, acrylic, or the like can be used. In the case where glass frit is used as the sealant, the element substrate 201 and the sealing substrate 206 are preferably glass substrates for high adhesion.

As described above, the active matrix light-emitting device can be fabricated. Note that the active matrix light-emitting device is described as an example of a light-emitting device in this embodiment, a passive matrix light-emitting device can be fabricated using the light-emitting element of one embodiment of the present invention, which is described in Embodiment 1.

Note that the structure described in this embodiment can be combined as appropriate with any of the structures described in the other embodiments.

### Embodiment 3

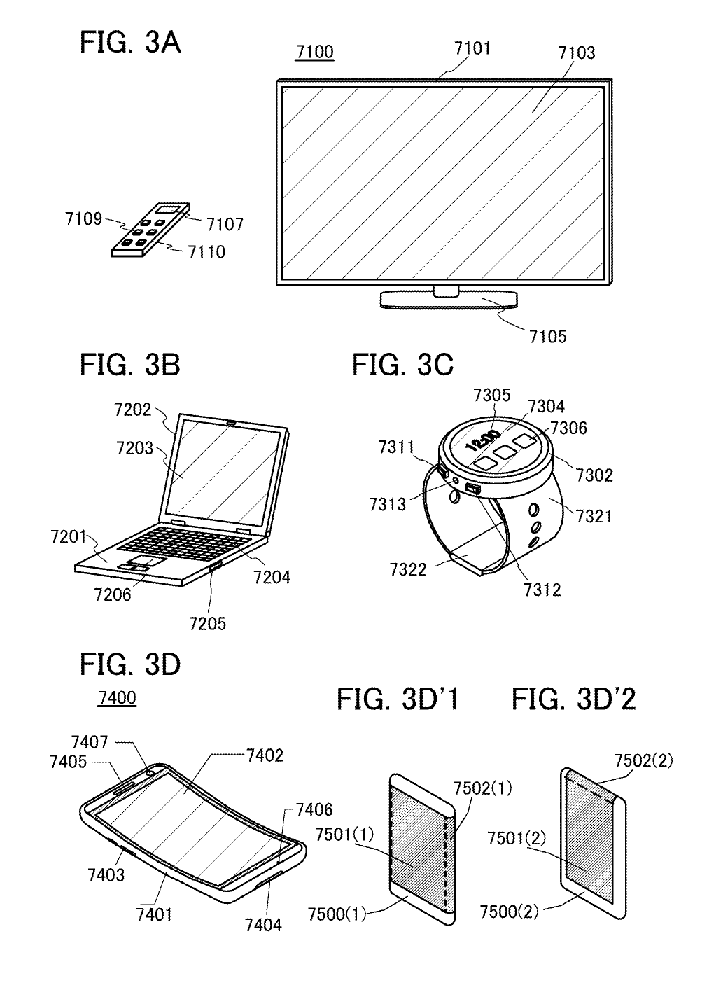

In this embodiment, examples of a variety of electronic devices that are completed using a light-emitting device, which is fabricated using the light-emitting element of one embodiment of the present invention, will be described with reference to FIGS. 3A to 3D.

Examples of electronic devices including the light-emitting device include television devices (also referred to as TV or television receivers), monitors for computers and the like, cameras such as digital cameras and digital video cameras, digital photo frames, mobile phones (also referred to as cellular phones or portable telephone devices), portable game machines, portable information terminals, audio playback devices, and large game machines such as pachinko machines. Specific examples of the electronic devices are illustrated in FIGS. 3A to 3D.

FIG. 3A illustrates an example of a television device. In a television device 7100, a display portion 7103 is incorporated in a housing 7101. Images can be displayed on the display portion 7103, and the light-emitting device can be used for the display portion 7103. In addition, here, the housing 7101 is supported by a stand 7105.

The television device 7100 can be operated by an operation switch of the housing 7101 or a separate remote controller 7110. With operation keys 7109 of the remote controller 7110, channels and volume can be controlled and images displayed on the display portion 7103 can be controlled. Furthermore, the remote controller 7110 may be provided with a display portion 7107 for displaying data output from the remote controller 7110.

Note that the television device 7100 is provided with a receiver, a modem, and the like. With the use of the receiver, general television broadcasts can be received. Moreover, when the television device is connected to a communication network with or without wires via the modem, one-way (from a sender to a receiver) or two-way (between a sender and a receiver or between receivers) information communication can be performed.

FIG. 3B illustrates a computer, which includes a main body 7201, a housing 7202, a display portion 7203, a keyboard 7204, an external connection port 7205, a pointing device 7206, and the like. Note that this computer can be manufactured using the light-emitting device for the display portion 7203.

FIG. 3C illustrates a smart watch, which includes a housing 7302, a display panel 7304, operation buttons 7311 and 7312, a connection terminal 7313, a band 7321, a clasp 7322, and the like.

The display panel 7304 mounted in the housing 7302 serving as a bezel includes a non-rectangular display region. The display panel 7304 can display an icon 7305 indicating time, another icon 7306, and the like.

The smart watch illustrated in FIG. 3C can have a variety of functions, for example, a function of displaying a variety of information (e.g., a still image, a moving image, and a text image) on a display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading program or data stored in a recording medium and displaying the program or data on a display portion.

The housing 7302 can include a speaker, a sensor (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone, and the like. Note that the smart watch can be manufactured using the light-emitting device for the display panel 7304.

FIG. 3D illustrates an example of a mobile phone (e.g., smartphone). A mobile phone 7400 includes a housing 7401 provided with a display portion 7402, a microphone 7406, a speaker 7405, a camera 7407, an external connection portion 7404, an operation button 7403, and the like. In the case where the light-emitting element of one embodiment of the present invention is formed over a flexible substrate, the light-emitting element can be used for the display portion 7402 having a curved surface as illustrated in FIG. 3D.

When the display portion 7402 of the mobile phone 7400 illustrated in FIG. 3D is touched with a finger or the like, data can be input to the mobile phone 7400. In addition, operations such as making a call and composing an e-mail can be performed by touch on the display portion 7402 with a finger or the like.

There are mainly three screen modes of the display portion 7402. The first mode is a display mode mainly for displaying an image. The second mode is an input mode mainly for inputting data such as text. The third mode is a display-and-input mode in which two modes of the display mode and the input mode are combined.

For example, in the case of making a call or creating e-mail, a character input mode mainly for inputting characters is selected for the display portion 7402 so that characters displayed on the screen can be input. In this case, it is preferable to display a keyboard or number buttons on almost the entire screen of the display portion 7402.

When a detection device such as a gyro sensor or an acceleration sensor is provided inside the mobile phone 7400, display on the screen of the display portion 7402 can be automatically changed by determining the orientation of the mobile phone 7400 (whether the mobile phone is placed horizontally or vertically).

The screen modes are changed by touch on the display portion 7402 or operation with the button 7403 of the housing 7401. The screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed for a certain period while a signal detected by an optical sensor in the display portion 7402 is detected, the screen mode may be controlled so as to be switched from the input mode to the display mode.

The display portion 7402 may function as an image sensor. For example, an image of a palm print, a fingerprint, or the like is taken by touch on the display portion 7402 with the palm or the finger, whereby personal authentication can be performed. In addition, when a backlight or a sensing light source that emits near-infrared light is provided in the display portion, an image of a finger vein, a palm vein, or the like can be taken.

Furthermore, the light-emitting device can be used for a mobile phone having a structure illustrated in FIG. 3D′1 or FIG. 3D′2, which is another structure of the mobile phone (e.g., smartphone).

Note that in the case of the structure illustrated in FIG. 3D′1 or FIG. 3D′2, text data, image data, or the like can be displayed on second screens 7502(1) and 7502(2) of housings 7500(1) and 7500(2) as well as first screens 7501(1) and 7501(2). Such a structure enables a user to easily see text data, image data, or the like displayed on the second screens 7502(1) and 7502(2) while the mobile phone is placed in user's breast pocket.

As described above, the electronic devices can be obtained using the light-emitting device that includes the light-emitting element of one embodiment of the present invention. Note that the light-emitting device can be used for electronic devices in a variety of fields without being limited to the electronic devices described in this embodiment.

Note that the structure described in this embodiment can be combined as appropriate with any of the structures described in the other embodiments.

### Embodiment 4

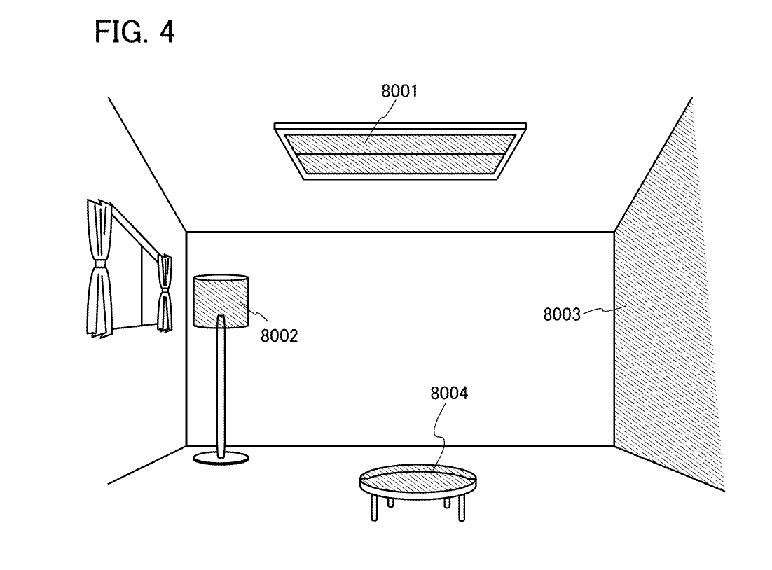

In this embodiment, examples of lighting devices each of which is provided with a light-emitting device including the light-emitting element of one embodiment of the present invention will be described with reference to FIG. 4.

FIG. 4 illustrates an example in which the light-emitting device is used as an indoor lighting device 8001. Since the light-emitting device can have a large area, it can be used for a lighting device having a large area. In addition, a lighting device 8002 having a curved light-emitting region can also be obtained with the use of a housing with a curved surface. A light-emitting element included in the light-emitting device described in this embodiment is in a thin film form, which allows the housing to be designed more freely. Thus, the lighting device can be elaborately designed in a variety of ways. In addition, a wall of the room may be provided with a large-sized lighting device 8003.

When the light-emitting device is used for a surface of a table, a lighting device 8004 that has a function as a table can be obtained. When the light-emitting device is used as part of other furniture, a lighting device that functions as the furniture can be obtained.

As described above, a variety of lighting devices that include the light-emitting device can be obtained. Note that these lighting devices are also embodiments of the present invention.

Note that the structure described in this embodiment can be combined as appropriate with any of the structures described in the other embodiments.

### Example 1

In this example, as the light-emitting element of one embodiment of the present invention, a light-emitting element that includes a non-formation region in part of a light-emitting layer was fabricated, and the properties thereof were compared with those of a light-emitting element that includes no non-formation region. Note that in this example, part of the light-emitting layer in the light-emitting element is deposited using a mesh mask so that the non-formation region is formed in part of the light-emitting layer.

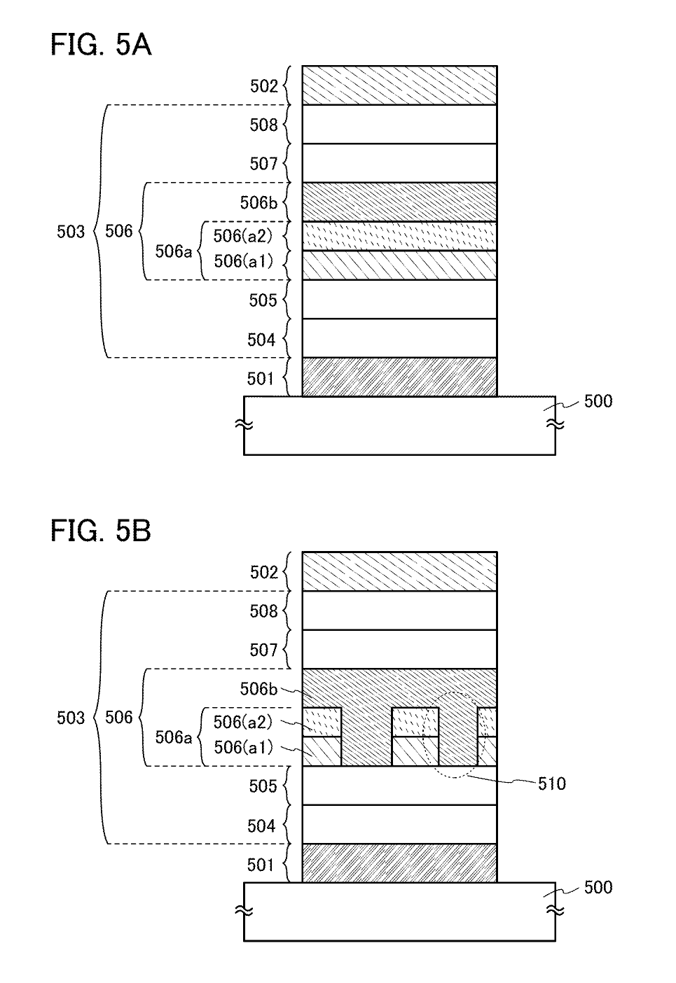

The light-emitting elements fabricated in this example will be described with reference to FIGS. 5A and 5B. Each of light-emitting elements 1 to 4 shown in this example has a structure in which a first electrode 501, a hole-injection layer 504, a hole-transport layer 505, a light-emitting layer 506, an electron-transport layer 507, an electron-injection layer 508, and a second electrode 502 are stacked over a substrate 500 as illustrated in FIGS. 5A and 5B.

FIG. 5A illustrates the light-emitting element 1. A first light-emitting layer 506a and a second light-emitting layer 506b included in the light-emitting layer 506 of the light-emitting element 1 are formed without using a mesh mask, and therefore the light-emitting layer 506 does not include a non-formation region. The light-emitting element 2 has a structure in which the light-emitting layer 506 in FIG. 5A includes only the second light-emitting layer 506b.

FIG. 5B illustrates the light-emitting elements 3 and 4 having the structure of the light-emitting element of one embodiment of the present invention. In the light-emitting elements 3 and 4, the first light-emitting layer 506a is deposited using a mesh mask so that a non-formation region 510 is provided. After that, the second light-emitting layer 506b is formed without using a mesh mask, whereby the second light-emitting layer 506b is formed in the non-formation region 510 as well as over the first light-emitting layer 506a. Note that the light-emitting elements 3 and 4 have different areas of the non-formation region 510 because the first light-emitting layer 506a is formed using mesh masks with different opening sizes. In other words, the proportion of the non-formation region 510 in the first light-emitting layer 506a is different between the light-emitting elements 3 and 4.

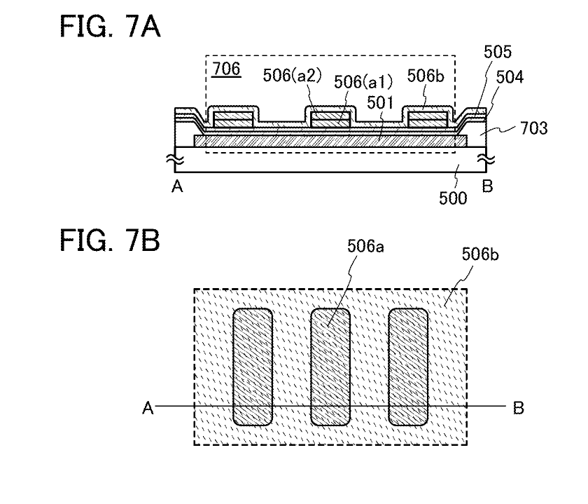

FIG. 7A shows a more specific cross-sectional structure of the light-emitting layer included in an EL layer 503 of the light-emitting element 3. Note that reference numerals are common to FIG. 5B and FIG. 7A. In FIG. 7A, edge portions of the first electrode (anode) 501 formed over the substrate 500 are covered with an insulator 703. The hole-injection layer 504 and the hole-transport layer 505 are stacked over the first electrode (anode) 501, and the first light-emitting layer 506a including a stack of a first layer 506a1 and a second layer 506a2 is formed thereover. The first light-emitting layer 506a is formed by an evaporation method using a mask, and therefore a region where the first light-emitting layer 506a is not formed (non-formation region) is provided on the same plane. Over the first light-emitting layer 506a, the second light-emitting layer 506b is formed without using a mask. Thus, the second light-emitting layer 506b is formed not only over the first light-emitting layer 506a but also over the hole-transport layer 505, i.e., in the non-formation region of the first light-emitting layer 506a. FIG. 7B is a top view of a region 706 surrounded by a dotted line in FIG. 7A. Note that the cross section AB shown in FIG. 7A corresponds to a cross-sectional view along the line AB in the top view of FIG. 7B. In a region of FIG. 7B, the second light-emitting layer 506b is stacked over the first light-emitting layer 506a (a first layer 506a1 and a second layer 506a2), and the other region has a single-layer structure in which the first light-emitting layer 506a (the first layer 506a1 and the second layer 506a2) is not formed and only the second light-emitting layer 506b is formed. Note that the light-emitting elements 3 and 4 are the same except that they have different areas of the non-formation region 510 because the first light-emitting layer 506a is formed using mesh masks with different opening sizes.

In this example, the first light-emitting layer 506a has a stacked structure of the first layer 506a1 and the second layer 506a2, which have different emission peaks. Moreover, the second light-emitting layer 506b stacked over the first light-emitting layer 506a has an emission peak different from the emission peaks of the first layer 506a1 and the second layer 506a2. Note that in the first light-emitting layer 506a of this example, the first layer 506a1 emits green light, the second layer 506a2 emits orange light, and the second light-emitting layer 506b emits blue light.

The following shows the structural formulae and abbreviations of materials used for the fabrication of the light-emitting elements in this example.

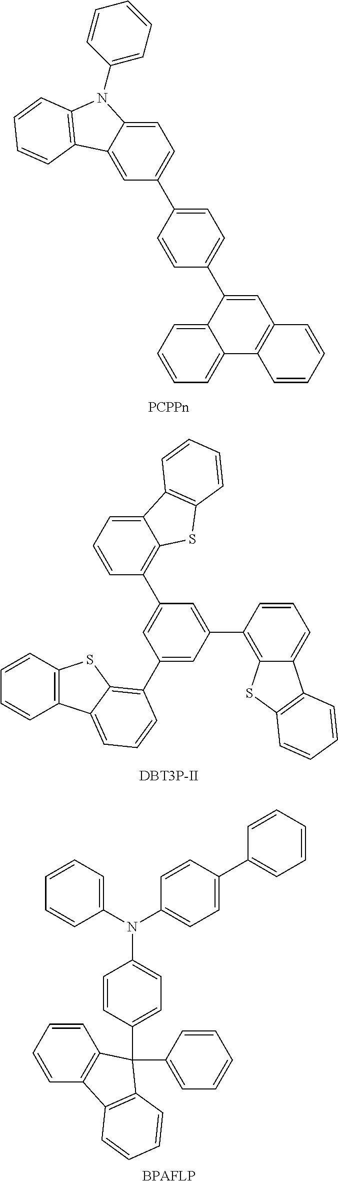

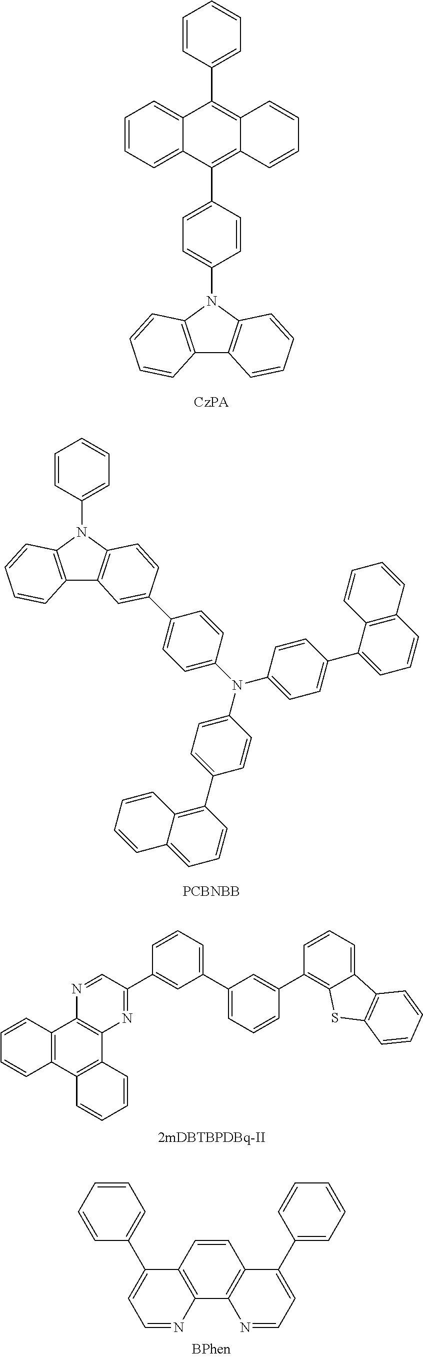

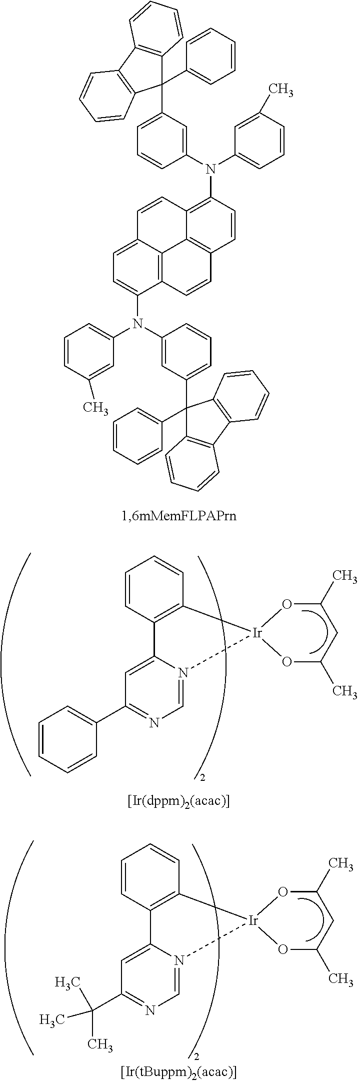

### <<Fabrication of Light-Emitting Elements 1 to 4>>

The first electrode 501, which serves as an anode, was formed in such a manner that indium tin oxide containing silicon or silicon oxide (ITSO) was deposited to a thickness of 110 nm over the glass substrate 500 by a sputtering method. The electrode area was set to 2 mm×2 mm.

As pretreatment, the surface of the substrate 500 was washed with water and then subjected to UV ozone treatment for 370 seconds. After that, the substrate 500 was transferred into a vacuum evaporation apparatus where the pressure had been reduced to approximately 10⁻⁴ Pa, and was subjected to vacuum baking at 170° C. for 30 minutes in a heating chamber of the vacuum evaporation apparatus, and then the substrate 500 was cooled down for approximately 30 minutes.

The EL layer 503 and the second electrode 502 are sequentially formed over the first electrode 501. Note that as illustrated in FIG. 5A, the EL layer 503 in the light-emitting element 1 includes the hole-injection layer 504, the hole-transport layer 505, the light-emitting layer 506 (the first light-emitting layer 506a and the second light-emitting layer 506b), the electron-transport layer 507, and the electron-injection layer 508. The first light-emitting layer 506a has a stack of a plurality of layers (the first layer 506a1 and the second layer 506a2) containing different substances. The light-emitting element 2 is different from the light-emitting element 1 in that the light-emitting layer 506b does not include the first light-emitting layer 506a and includes only the second light-emitting layer 506b. As illustrated in FIG. 5B, in the light-emitting elements 3 and 4, the non-formation region is included in part of the first light-emitting layer 506a in the light-emitting layer 506 (the first light-emitting layer 506a and the second light-emitting layer 506b). Thus, in this example, parts that are the same in the light-emitting elements 1 to 4 are collectively described, and only different parts are described individually.

After reducing the pressure of the vacuum evaporation apparatus to 10⁻⁴ Pa, 1,3,5-tri(dibenzothiophen-4-yl)benzene (abbreviation: DBT3P-II) and molybdenum oxide were co-evaporated at a mass ratio of 2:1 (DBT3P-II: molybdenum oxide), whereby the hole-injection layer 504 was formed over the first electrode 501. Note that the co-evaporation is an evaporation method in which a plurality of different substances are vaporized from the respective evaporation sources at the same time. Note that the thickness of the hole-injection layer 504 was set to 30 nm in each of the light-emitting elements 1 to 4.

In the light-emitting elements 1 to 3, the hole-transport layer 505 was formed over the hole-injection layer 504 by depositing 3-[4-(9-phenanthryl)-phenyl]-9-phenyl-9H-carbazole (abbreviation: PCPPn) to a thickness of 20 nm. In the light-emitting element 4, the hole-transport layer 505 was formed over the hole-injection layer 504 by depositing 4-phenyl-4′-(9-phenylfluoren-9-yl)triphenylamine (abbreviation: BPAFLP) to a thickness of 20 nm.

In the light-emitting layer 506 of light-emitting element 1, the first light-emitting layer 506a has a stacked structure of the first layer 506a1 and the second layer 506a2 whereas the second light-emitting layer 506b has a single-layer structure. Note that the first layer 506a1 was formed by co-evaporation of 2-[3′-(dibenzothiophen-4-yl)biphenyl-3-yl]dibenzo[f,h]quinoxaline (abbreviation: 2 mDBTBPDBq-II), 4,4′-di(1-naphthyl)-4″-(9-phenyl-9H-carbazol-3-yl)triphenylamine (abbreviation: PCBNBB), and (acetylacetonato)bis(6-tert-butyl-4-phenylpyrimidinato)iridium(III) (abbreviation: [Ir(tBuppm)₂(acac)]) at a mass ratio of 0.7:0.3:0.05 (2mDBTBPDBq-II: PCBNBB: [Ir(tBuppm)₂(acac)]). The thickness of the first layer 506a1 was set to 10 nm. The second layer 506a2 was formed by co-evaporation of 2mDBTBPDBq-II, PCBNBB, and (acetylacetonato)bis(4,6-diphenylpyrimidinato)iridium(III) (another name: bis[2-(6-phenyl-4-pyrimidinyl-κN3)phenyl-κC](2,4-pentanedionato-κ²O,O′)iridium(III)) (abbreviation: [Ir(dppm)₂(acac)]) at a mass ratio of 0.8:0.2:0.05 (2mDBTBPDBq-II: PCBNBB: [Ir(dppm)₂(acac)]). The thickness of the second layer 506a2 was set to 20 nm. The second light-emitting layer 506b was formed by co-evaporation of 9-[4-(10-phenyl-9-anthracenyl)phenyl]-9H-carbazole (abbreviation: CzPA) and N,N-bis(3-methylphenyl)-N,N′-bis[3-(9-phenyl-9H-fluoren-9-yl)phenyl]-pyrene-1,6-diamine (abbreviation: 1,6mMemFLPAPrn) at a mass ratio of 1:0.05 (CzPA: 1,6mMemFLPAPrn). The thickness of the second light-emitting layer 506b was set to 20 nm.

In the light-emitting element 2, the first light-emitting layer 506a is not formed and only the second light-emitting layer 506b is formed. Hence, the second light-emitting layer 506b was formed by co-evaporation of CzPA and 1,6mMemFLPAPrn at a mass ratio of 1:0.05 (CzPA: 1,6mMemFLPAPrn). The thickness of the second light-emitting layer 506b was set to 20 nm.

The light-emitting elements 3 and 4 have a stacked structure similar to that of the light-emitting element 1: the first light-emitting layer 506a has a stacked structure of the first layer 506a1 and the second layer 506a2 whereas the second light-emitting layer 506b has a single-layer structure. In addition, the materials, compositions, and thicknesses of the light-emitting elements 3 and 4 are the same as those of the light-emitting element 1. The light-emitting elements 3 and 4 are different from the light-emitting element 1 in that the first light-emitting layer 506a (the first layer 506a1 and the second layer 506a2) is formed using a mesh mask. Note that the first light-emitting layer 506a in the light-emitting elements 3 and 4 was produced using as a mask an ultrafine nano-mesh fabricated by Clever Co., Ltd, which was a 100% nickel layered film. The details of the mesh mask used for each element are listed below in Table 1. Note that in Table 1, the number of meshes denotes the number of apertures between the centers of 25.4-mm (1-inch) wires; the aperture width, the length between wires; and the wire diameter, the diameter of a wire. The transmittance is the proportion (%) of the area of the first light-emitting layer 506a (the first layer 506a1 and the second layer 506a2) in the light-emitting layer of the light-emitting elements 3 and 4. In other words, the area proportion (%) of the non-formation region in the light-emitting layer can be obtained by 100(%)−transmittance (%).

TABLE 1

| | | aperture | wire | | |
|---|---|---|---|---|---|
| | mesh | width | diam- | thick- | transmit- |
| | number | (μm) | eter(μm) | ness(μm) | tance(%) |
| mask 1 (for | 150 | 114 | 55 | 43 | 48 |
| light-emitting | | | | | |
| elment 3) | | | | | |
| mask 2 (for | 500 | 20 | 31 | 20 | 20 |
| light-emitting | | | | | |
| element 4) | | | | | |

Note that the first light-emitting layer 506a (the first layer 506a1 and the second layer 506a2) was formed while the aforementioned mask was fixed to a deposition target substrate.

By using the aforementioned mask for forming the first light-emitting layer 506a (the first layer 506a1 and the second layer 506a2), the non-formation region 510 illustrated in FIG. 5B can be provided.

The electron-transport layer 507 was formed by evaporation of CzPA (5 nm in thickness) over the light-emitting layer 506 and then evaporation of BPhen (15 nm in thickness).

The electron-injection layer 508 was formed by evaporation of lithium fluoride (LiF) (1 nm in thickness) over the electron-transport layer 507.

The second electrode 502, which serves as a cathode, was formed in such a manner that aluminum was deposited to a thickness of 200 nm over the electron-injection layer 508. Note that a resistance-heating method was used in all the above evaporation steps.

Note that each of the fabricated light-emitting elements 1 to 4 was sealed in a glove box containing a nitrogen atmosphere so as not to be exposed to the air (specifically, a sealant was applied to an outer edge of the light-emitting element, irradiation with ultraviolet light with a wavelength of 365 nm was performed at 6 J/cm², and heat treatment was performed at 80° C. for 1 hour).

Table 2 shows the structures of the light-emitting elements 1 to 4 fabricated as described above. Note that the first layer 506a1 in the first light-emitting layer 506a in the light-emitting elements 1, 3, and 4, the second layer 506a2 in the light-emitting elements 1, 3, and 4, and the second light-emitting layer 506b in the light-emitting elements 1 to 4 are represented as *¹, *², and *³, respectively, in the margin of Table 2.

TABLE 2

| | | | | light-emitting layer | | | | | | |
|---|---|---|---|---|---|---|---|---|---|---|
| | first | hole- | hole- | first light-emitting layer | | second light- | electron- | | electron- | second |
| | electrode | injection layer | transport layer | first layer | second layer | emitting layer | transport layer | | injection layer | electrode |
| light- | ITSO | DBT3P- II: | PCPPn | *¹ | *² | *³ | CzPA | BPhen | LiF | Al |
| emitting | (110 nm) | MoOx | (20 nm) | (no mask) | (no mask) | | (5 nm) | (15 nm) | (1 nm) | (200 nm) |
| element 1 | | (2:1 30 nm) | | | | | | | | |
| light- | | | | | | | | | | |
| emitting | | | | | | | | | | |
| element 2 | | | | | | | | | | |
| light- | | | | *¹ | *² | | | | | |
| emitting | | | | (mask 1) | (mask 1) | | | | | |
| element 3 | | | | | | | | | | |
| light- | | | BPAFLP | *¹ | *² | | | | | |
| emitting | | | (20 nm) | (mask 2) | (mask 2) | | | | | |
| element 4 | | | | | | | | | | |

*¹ 2mDBTBPDBq-II:PCBNBB:[Ir(tBuppm)₂(acac)] (0.7:0.3:0.05 10 nm)
*² 2mDBTBPDBq-II:PCBNBB:[Ir(dppm)₂(acac)] (0.8:0.2:0.05 20 nm)
*³ CzPA:1,6mMemFLAPm (1:0.05 20 nm)

### <<Properties of Light-Emitting Elements 1 to 4>>

Table 3 shows the measurement results of the fabricated light-emitting elements 1 to 4 that were kept at room temperature (25° C.). Note that the results in Table 3 show the main initial properties of the light-emitting elements at approximately 1000 cd/m². In Table 3, duv denotes a deviation from blackbody locus.

TABLE 3

| | | | power | external quantum | color | | general color |
|---|---|---|---|---|---|---|---|
| | voltage | chromaticity | efficiency | efficiency | temperature | | rendering |
| | (V) | (x, y) | (lm/W) | (%) | (K) | duv | index: Ra |
| light-emitting | 3.2 | (0.49, 0.50) | 85 | 27 | 2870 | 0.026 | 34 |
| element 1 | | | | | | | |
| light-emitting | 3.0 | (0.14, 0.19) | 11 | 8 | — | — | — |
| element 2 | | | | | | | |
| light-emitting | 3.0 | (0.46, 0.46) | 48 | 15 | 3020 | 0.018 | 44 |
| element 3 | | | | | | | |
| light-emitting | 3.0 | (0.41, 0.42) | 26 | 9 | 3570 | 0.011 | 53 |
| element 4 | | | | | | | |

The above results show that among the light-emitting elements fabricated in this example, the light-emitting elements including the stacked light-emitting layers (the first light-emitting layer 506a and the second light-emitting layer 506b), i.e., the light-emitting elements 1, 3, and 4, have higher power efficiency and external quantum efficiency than the light-emitting element 2 including the single light-emitting layer (the second light-emitting layer 506b). In the light-emitting elements 3 and 4, in which the non-formation region 510 is included in part of the light-emitting layer, the proportion (the area ratio (%)) of the non-formation region 510 in the light-emitting layer is 52% and 80%, respectively, which is included in the desired range of 5% to 95% (more preferably, 40% to 90%). The above results also reveal that the light-emitting elements 3 and 4 emit light in the range of incandescent light (2600 K to 3250 K) or warm white light (3250 K to 3800 K), which is a desired range of the correlated color temperature range defined by JIS (2600 K to 7100 K).

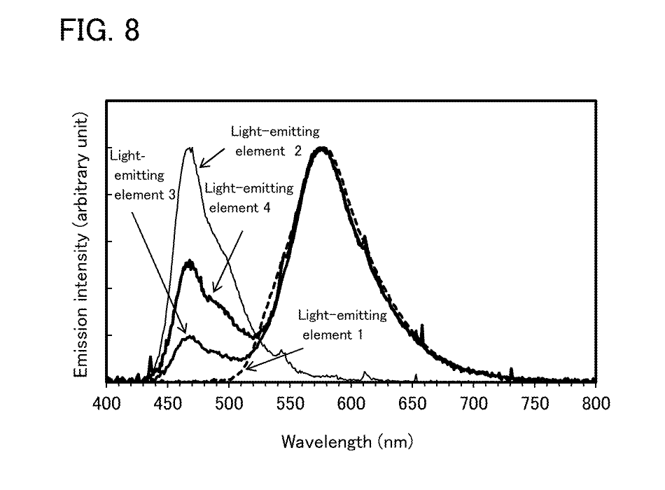

FIG. 8 shows the emission spectra of the light-emitting elements 1 to 4 in the initial operation where a current is supplied at a density of 3.75 mA/cm². The light-emitting element 1 includes the light-emitting layer 506 with a stacked structure and each light-emitting layer contains a different light-emitting substance; however, light from only the first light-emitting layer 506a, which has an emission spectrum peak at approximately 578 nm, was observed. The light-emitting element 2 includes the light-emitting layer 506 with only the second light-emitting layer 506b; hence, light from the second light-emitting layer 506b, which has an emission spectrum peak at approximately 467 nm, was obtained. As for the light-emitting elements 3 and 4 in which the non-formation region 510 is included in part of the light-emitting layer 506, light from only the first light-emitting layer 506a, which has an emission spectrum peak at approximately 578 nm, was found in addition to light from the second light-emitting layer 506b, which has an emission spectrum peak at approximately 467 nm. Note that the intensity of light from the second light-emitting layer 506b was different between the light-emitting elements 3 and 4. This is probably because of a difference in the shape of the non-formation region 510 in the light-emitting layer 506 between the light-emitting elements 3 and 4.

Note that the correlated color temperature of the light-emitting element is determined by the emission colors and intensities of lights from the light-emitting element. When the non-formation region is provided in part of the light-emitting layer as shown in this example, the correlated color temperature of the light-emitting element can be controlled to obtain a desired light.

This application is based on Japanese Patent Application serial No. 2014-086196 filed with Japan Patent Office on Apr. 18, 2014, the entire contents of which are hereby incorporated by reference.

What is claimed is:

1. A light-emitting element comprising:
a pair of electrodes; and
a light-emitting layer between the pair of electrodes, the light-emitting layer comprising a first light-emitting layer and a second light-emitting layer,
wherein the light-emitting layer comprises a first region where the first light-emitting layer and the second light-emitting layer overlap with each other and a second region where the first light-emitting layer is not formed.

2. The light-emitting element according to claim 1,
wherein the first region and the second region overlap with the pair of electrodes.

3. The light-emitting element according to claim 1,
wherein the first region is surrounded by the second region.

4. The light-emitting element according to claim 1,
wherein light emitted from the light-emitting layer comprises a first emission spectrum obtained from the first region and a second emission spectrum obtained from the second region.

5. The light-emitting element according to claim 1,
wherein a first light emitted from the first region is different in color from a second light emitted from the second region.

6. The light-emitting element according to claim 4,
wherein the first emission spectrum has a peak in a range of 500 nm to 650 nm, and
wherein the second emission spectrum has a peak in a range of 400 nm to 500 nm.

7. The light-emitting element according to claim 1,
wherein the first light-emitting layer emits an yellow-orange light and the second light-emitting layer emits a blue light.

8. The light-emitting element according to claim 1,
wherein the first light-emitting layer comprises a stack of a layer containing a green-light-emitting substance and a layer containing an orange-light-emitting substance.

9. The light-emitting element according to claim 1,
wherein the first light-emitting layer contains a phosphorescent substance and the second light-emitting layer contains a fluorescent substance.

10. The light-emitting element according to claim 1,
wherein the first region has one of a substantially rectangular shape, a substantially square shape, a circular shape, a triangular shape, and an elliptical shape.

11. A light-emitting device comprising the light-emitting element according to claim 1.

12. An electronic device comprising the light-emitting device according to claim 11.

13. A lighting device comprising the light-emitting device according to claim claim 11.

14. A light-emitting element comprising:
a pair of electrodes; and
a light-emitting layer between the pair of electrodes, the light-emitting layer comprising a first light-emitting layer including a first light-emitting substance and a second light-emitting layer including a second light-emitting substance,
wherein the first light-emitting substance and the second light-emitting substance emit light with different colors from each other, and
wherein the light-emitting layer comprises a first region where the first light-emitting layer and the second light-emitting layer overlap with each other and a second region where one of the first light-emitting layer and the second light-emitting layer is not formed.

15. The light-emitting element according to claim 14,
wherein the first region and the second region overlap with the pair of electrodes.

16. The light-emitting element according to claim 14,
wherein the first region is surrounded by the second region.

17. The light-emitting element according to claim 14,
wherein a first light emitted from the first region is different in color from a second light emitted from the second region, and
wherein the light-emitting layer is configured to emit the first light and the second light at the same time.

18. The light-emitting element according to claim 14,
wherein a first light emitted from the first region is different in color from a second light emitted from the second region.

19. The light-emitting element according to claim 14,
wherein the first light-emitting layer emits an yellow-orange light and the second light-emitting layer emits a blue light.

20. The light-emitting element according to claim 14,
wherein the first light-emitting layer comprises a stack of a layer containing a green-light-emitting substance and a layer containing an orange-light-emitting substance.

21. The light-emitting element according to claim 14,
wherein the first light-emitting layer contains a phosphorescent substance and the second light-emitting layer contains a fluorescent substance.

22. The light-emitting element according to claim 14,
wherein the first region has one of a substantially rectangular shape, a substantially square shape, a circular shape, a triangular shape, and an elliptical shape.

23. A light-emitting device comprising the light-emitting element according to claim 14.

24. An electronic device comprising the light-emitting device according to claim 23.

25. A lighting device comprising the light-emitting device according to claim 23.

26. A light-emitting element comprising:
a pair of electrodes; and
a light-emitting layer between the pair of electrodes, the light-emitting layer comprising a first light-emitting layer emitting phosphorescence and a second light-emitting layer emitting fluorescence,
wherein the light-emitting layer comprises a first region where the first light-emitting layer and the second light-emitting layer overlap with each other and a second region where one of the first light-emitting layer and the second light-emitting layer is not formed,
wherein a first light emitted from the first region is different in color from a second light emitted from the second region.

27. The light-emitting element according to claim 26,
wherein the first region and the second region overlap with the pair of electrodes.

28. The light-emitting element according to claim 26,
wherein the first region is surrounded by the second region.

29. The light-emitting element according to claim 26,
wherein the light-emitting layer is configured to emit the first light and the second light at the same time.

30. The light-emitting element according to claim 26,
wherein the first light-emitting layer comprises a layer in which an exciplex is formed.

31. The light-emitting element according to claim 26,
wherein the second light-emitting layer comprises a fluorescent substance and a host material having a Ti level lower than that of the fluorescent substance.

32. The light-emitting element according to claim 26,
wherein the first light-emitting layer emits an yellow-orange light and the second light-emitting layer emits a blue light.

33. The light-emitting element according to claim 26,
wherein the first light-emitting layer comprises a stack of a layer containing a green-light-emitting substance and a layer containing an orange-light-emitting substance.

34. The light-emitting element according to claim 26,
wherein the first region has one of a substantially rectangular shape, a substantially square shape, a circular shape, a triangular shape, and an elliptical shape.

35. A light-emitting device comprising the light-emitting element according to claim 26.

36. An electronic device comprising the light-emitting device according to claim 35.

37. A lighting device comprising the light-emitting device according to claim 35.
